(19) United States
(12) Patent Application Publication
(10) Pub. No.: US 2021/0292898 A1
(43) Pub. Date: Sep. 23, 2021

(54) Pedestal Geometry for Fast Gas Exchange

(71) Applicant: Applied Materials, Inc., Santa Clara, CA (US)

(72) Inventors: Sanjeev Baluja, Campbell, CA (US); Tejas Ulavi, San Jose, CA (US); Ashutosh Agarwal, San Jose, CA (US)

(73) Assignee: Applied Materials, Inc., Santa Clara, CA (US)

(21) Appl. No.: 17/204,428

(22) Filed: Mar. 17, 2021

Related U.S. Application Data
(60) Provisional application No. 62/992,980, filed on Mar. 21, 2020.

(51) Int. Cl. C23C 16/458; C23C 16/44; C23C 16/52

(52) U.S. Cl. CPC C23C 16/4587; C23C 16/52; C23C 16/4581; C23C 16/4412

(57) ABSTRACT

Apparatus and methods for providing backside pressure control and edge purge gas to a substrate in a processing chamber. A support region of a substrate support is defined by an outer band. The support region comprises one or more openings in the top surface of the substrate support. The outer band comprises a plurality of spaced apart posts. Processing chambers, methods of processing a substrate and non-transitory computer-readable medium containing instructions to process a substrate are also disclosed.

### CROSS-REFERENCE TO RELATED APPLICATIONS

This application claims priority to U.S. Provisional Application No. 62/992,980, filed Mar. 21, 2020, the entire disclosure of which is hereby incorporated by reference herein.

### TECHNICAL FIELD

Embodiments of the disclosure are directed to substrate support components. In particular, embodiments of the disclosure are directed to substrate supports with improved gas exchange.

### BACKGROUND

In a semiconductor wafer processing chamber, such as an atomic layer deposition (ALD) chamber, wafer edge purging and backside pressure control are useful features. The primary functions of these features are to provide backside pressure control to improve temperature uniformity of the wafer and edge purging to prevent deposition on the backside and edge of the wafer.

In many ALD process chamber, a wafer chucked to a pedestal is moved back and forth between two or more process stations. Each portion of the deposition cycle includes a period of time in which the wafer is exposed to a dose of a reactive gas and a period of time in which the process station is purged to remove unreacted species.

Conventional edge purge can be accomplished by a couple different techniques. Gas can be delivered through a line in the pedestal and distributed to the edges underside of the wafer edge through either a recursive channel, a plenum near the circumference of the pedestal, or a combination of both. The purge techniques are limited in effectiveness based on how well the flow can be distributed around the edge of the wafer.

In many process environments, the wafer is positioned within a pocket formed in the substrate support. An active bevel purge can be incorporated into the pedestal but occupies a significant amount of space and can be difficult to employ with moving substrate supports. Without an active purge, there exists a dead-volume or recirculation zone between the wafer edge and the pocket in the substrate support. As wafers are moved between process stations, residual precursors can remain in this dead volume and lead to undesirable gas phase reactions on the wafer edge. These gas phase depositions can adversely affect the film composition, resistivity and/or conformality.

For both backside pressure control and edge purging, any features put into a pedestal will impact other design components and goals. For example, putting a gas distribution channel in a pedestal will have a negative impact on the temperature uniformity that can be achieved with that pedestal due to required design compromises.

Therefore, there is a need in the art for substrate support apparatus with improved edge purge.

### SUMMARY

One or more embodiments of the disclosure are directed to substrate support pedestals comprising a support body with a top surface and a bottom surface that define a thickness. The top surface has a support region bounded by an outer band and comprises one or more openings. The outer band comprises a plurality of spaced apart posts.

Additional embodiments of the disclosure are directed to processing chambers comprising a substrate support assembly and a plurality of gas distribution assemblies. The substrate support assemblies comprise a plurality of substrate support pedestals, each of the substrate support pedestals comprising a support body with a top surface and a bottom surface defining a thickness. The top surfaces have a support region bounded by an outer band and comprise one or more openings in the top surfaces. The outer bands comprise a plurality of spaced apart posts. The substrate support assembly is rotatable around a central axis. The plurality of gas distribution assemblies are spaced around an inside of the processing chamber. Each of the gas distribution assemblies is configured to direct a flow of gas toward the top surface of the support body.

Further embodiments of the disclosure are directed to processing methods comprising: providing a flow of gas to a support region of a substrate support pedestal, the substrate support pedestal comprising, a support body having a top surface and a bottom surface defining a thickness, the top surface having a support region bounded by an outer band and comprising one or more openings in the top surface, the outer band comprising a plurality of spaced apart posts; and evacuating the support region to provide a purge flow from the support region pas the spaced apart posts bounding the support region.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 shows a cross-sectional schematic view of a processing chamber in accordance with one or more embodiment of the disclosure;

FIG. 2 shows a parallel projection view of a substrate support pedestal according to one or more embodiment of the disclosure;

FIG. 3 shows a partial cross-sectional view of a substrate support pedestal according to one or more embodiment of the disclosure;

FIG. 4 shows a partial cross-sectional schematic view of the substrate support pedestal of FIG. 2 taken along line 4-4′;

FIG. 5 shows a partial cross-sectional schematic view of the substrate support pedestal of FIG. 2 taken along line 5-5′;

FIG. 6 shows a partial cross-sectional schematic view of a substrate support pedestal according to one or more embodiment of the disclosure; and

FIG. 7 shows a schematic top view of an outer band according to one or more embodiment of the disclosure;

FIG. 8A shows a schematic top view of an outer band according to one or more embodiment of the disclosure;

FIG. 8B shows a schematic top view of a pedestal assembly with multiple substrate support pedestals according to one or more embodiment of the disclosure;

FIG. 9A shows a parallel projection view of a post according to one or more embodiment of the disclosure;

FIG. 9B shows a schematic top view of a pedestal using the post of FIG. 9A;

FIG. 10A shows a parallel projection view of a post according to one or more embodiment of the disclosure;

FIG. 11B shows a schematic top view of a pedestal using the post of FIG. 10A;

FIG. 11A shows a parallel projection view of a post according to one or more embodiment of the disclosure; and

FIG. 11B shows a schematic top view of a pedestal using the post of FIG. 11A.

### DETAILED DESCRIPTION

Embodiments of the disclosure are directed to apparatus and methods for integrating backside pressure control and edge purge in a process chamber. In some embodiments, backside pressure control is achieved by creating a controlled leak through the seal band so that the backside pressure control gas will also function as the edge purge gas.

Some embodiments of the disclosure advantageously provide apparatus and methods to create or improve edge purge gas flow uniformity and/or efficiency. With a more uniform edge purge gas, the flow rate of the edge purge gas in some embodiments is reduced. Some embodiments advantageously eliminate annular dead volume around the edge of a wafer. Some embodiments maintain the benefits of a heater pocket to center and capture a wafer while improved purge efficiency.

Some embodiments of the disclosure provide a movable heater/substrate support which incorporate posts. The posts of some embodiments form a boundary for a support region of the substrate support that acts similarly to the pocket. For example, the support region bounded by posts of some embodiments minimizes local thermal effects without creating dead volumes around the wafer. In some embodiments, the outer band provides a physical barrier to keep the substrate centered on the support region within the band. In some embodiments, there is substantially no dead volume around the substrate. In some embodiments, the wafer edge becomes part of the active flow path, improving purge efficiency and cycle times. In some embodiments, the wafer edge is thermally and chemically less sensitive to centering or hand-off effects.

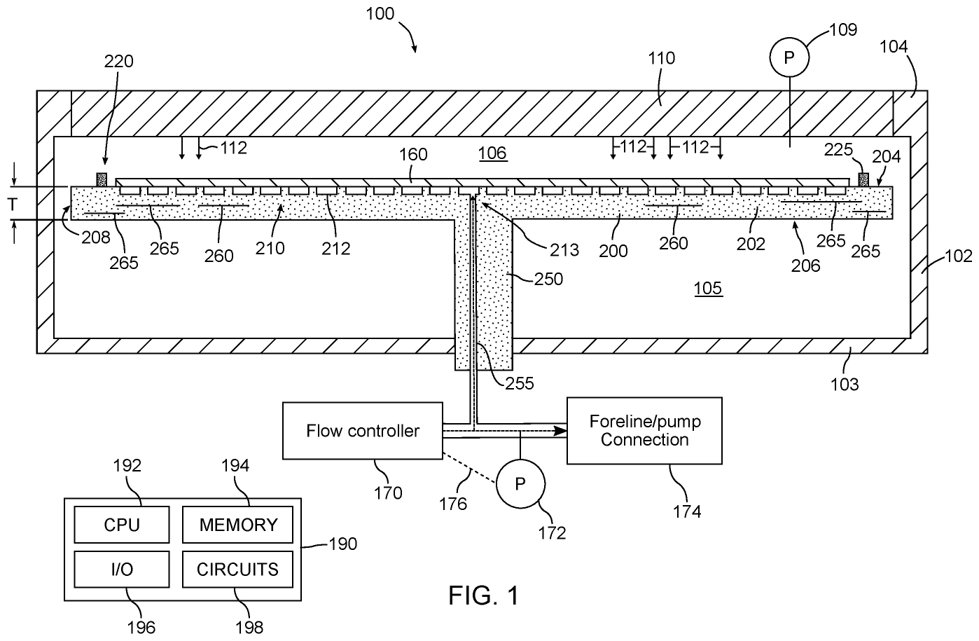

Referring to FIG. 1, one or more embodiments of the disclosure are directed to substrate support pedestals 200 and processing chambers 100 comprising the substrate support pedestals 200. The processing chamber 100 illustrated in FIG. 1 comprises a chamber wall 102, bottom 103 and top 104 enclosing an interior volume 105. A gas distribution assembly 110 is within the processing chamber 100 to provide a flow of gas 112 into the interior volume 105.

In the illustrated embodiment, the gas distribution assembly 110 is part of the chamber top 104. However, the skilled artisan will recognize that the gas distribution assembly 110 can be separate from the chamber top 104 or located in a different portion of the interior volume 105 of the processing chamber 100. For example, in some embodiments, the gas distribution assembly provides a flow of gas from a sidewall 102 of the chamber 100 at an oblique angle relative to the top surface of the substrate support.

FIGS. 1 through 6 illustrate a substrate support pedestal 200 according to various embodiments of the disclosure. The substrate support pedestal 200 includes a support body 202 for supporting a wafer or substrate during processing. The support body 202 has a top surface 204 and bottom surface 206 that defines a thickness T of the support body 202. The support body 202 has an outer edge 208 which defines a general shape of the support body 202. In some embodiments, the support body 202 is a generally cylindrical component having a circular outer edge 208 and thickness T.

The top surface 204 of the support body 202 has a support region 210. The support region 210 is a portion of the top surface 204 designated to hold a substrate during processing. The support region 210 of some embodiments comprises one or more openings 212 in the top surface 204. The one or more openings 212 of some embodiments are in fluid communication with one or more of a vacuum source, a reactive gas source or a purge gas source.

The embodiments illustrated in the Figures show substrate support pedestals 200 for use with round substrates. However, the skilled artisan will recognize that the disclosure is not limited to round substrates and round support bodies 202 and that any suitable shape substrate and support body can be used.

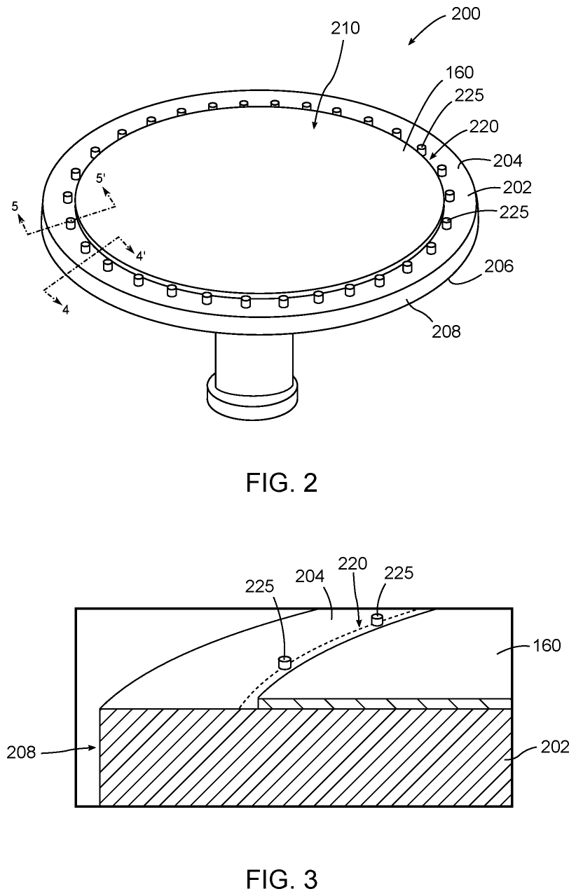

The support region 210 is bounded by an outer band 220 comprising a plurality of spaced apart posts 225. As used in this specification and the appended claims, the term “band” refers to region with posts 225 with top surface 204 between. A “band” refers to the overall impression and arrangement of the posts 225, and does not imply any particular shape. FIGS. 2 and 3 show a substrate 160 on the top surface 204 of the pedestal 200. The outer band 220 is formed by the spaced posts 225 that surround the outer peripheral edge 161 of the substrate 160.

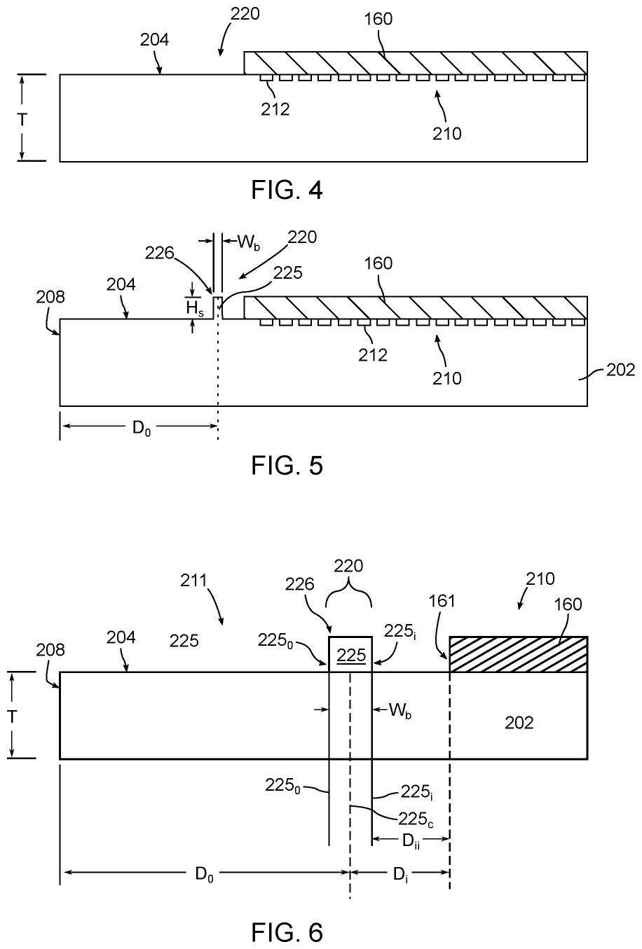

FIGS. 4 through 6 illustrate expanded views of the pedestal 200 according to one or more embodiments of the disclosure. FIG. 4 shows a partial cross-sectional view along line 4-4′ of the embodiment illustrated in FIG. 2. The embodiment illustrated in FIGS. 3 and 4 are similar in that both show the pedestal 200 in cross-section at a region of the band 220 (shown as dotted line in FIG. 3) in which there is no post 225. FIG. 5 shows a partial cross-sectional view along line 5-5′ of the embodiment illustrated in FIG. 2 taken through a region of the band 220 in which there is a post 225. FIG. 6 shows a schematic representation of FIG. 5 for further descriptive purposes.

FIGS. 5 and 6 illustrate the band 220 as having a width W_{b}. The width Wb is measured from the edge 225o of the post 225 closest to the outer edge 208 of the body 202 to the edge 225i of the post 225 closest to the outer peripheral edge 161 of the substrate 160. The support region 210 of the top surface 204 is the portion of the body 202 within the bounds of the edge 225i of the posts 225.

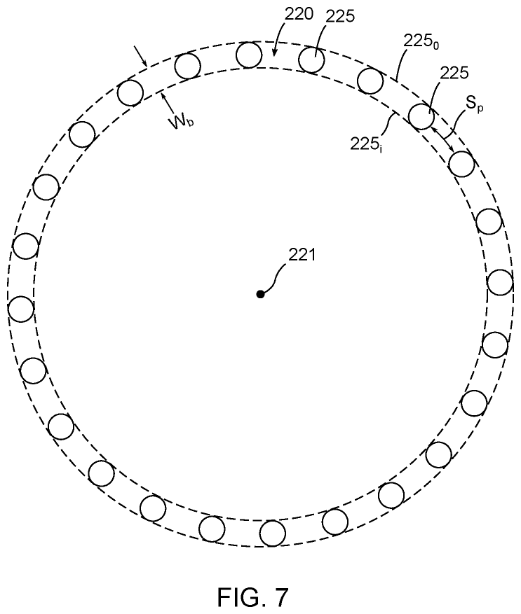

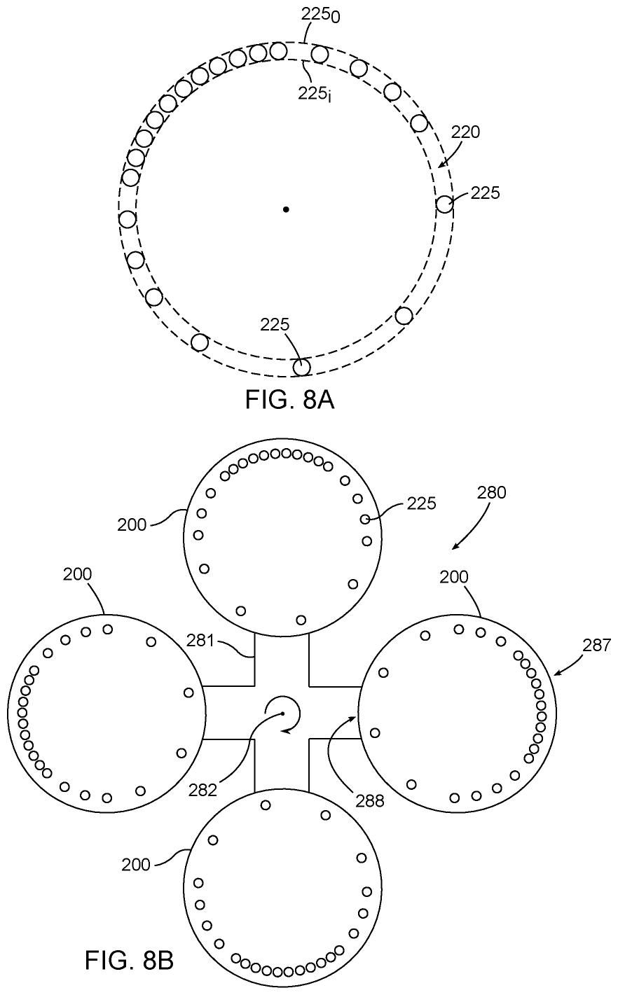

FIG. 7 illustrates a schematic view of a band 220 represented by a circular arrangement of 24 posts 225. Each of the posts 225 illustrated is rotated relative to the center axis 221 by 15°. The spacing Sₚ between adjacent posts 225 of some embodiments is uniform. As used in this manner, uniform spacing means that any given space Sp is within 5%, 2%, 1% or 0.5% of the average space between posts 225. In some embodiments, the spacing Sₚ between posts 225 is variable. For example, the posts 225 of some near one side of the band 220 in some embodiments are closer together than the posts 225 on an opposite side of the band 220, as shown in FIG. 8A.

The spaced apart posts 225 of some embodiments provide substantially no barrier to gas flow from the support region 210. The cross-sectional width of the individual posts 225, measured tangentially to the band 220 at the angle of the post 225, is small compared to the area of the support region 210. In some embodiments, the combined cross-sectional widths of the spaced apart posts 225 is less than or equal to 50% of the circumference of the support region 210, or the average circumference of the band 220. In some embodiments, the combined cross-sectional widths of the spaced apart posts is less than or equal to 25%, 20%, 15%, 10%, 5%, 2% or 1% of the circumference of the support region 210, or the average circumference of the band 220.

FIG. 8B illustrates a substrate support assembly 280 according to one or more embodiment of the disclosure. The assembly 280 has a cruciform shaped support base 281 with four substrate supports 200 at the end of each leg of the support 281. The four substrate supports 200 are rotated around a central axis 282 of the support base 281. As illustrated in the embodiment of FIG. 8B, the posts 225 have a higher density (smaller spacing Sₚ) on a side 287 of the pedestal 200 that is furthest from the central axis 282 of the offset support assembly than the side 288 closest to the central axis 282, as shown in FIG. 8B.

Referring back to FIG. 6, the band 220 is spaced a distance Dₒ from the outer peripheral 208 of the pedestal to separate the support region 210 from the outer region 211. In some embodiments, the band 220 is spaced a distance Dᵢ from the outer peripheral edge 161 of the substrate 160. The distances Dₒ and Dᵢ are measured to the center 225c of the width W_{b} of the band 220.

The distance from the outer edge 208 of the pedestal to the band 220 can be any suitable distance. In some embodiments, the distance Dₒ of the band 220 to the outer edge 208 of the pedestal is in the range of about 0.25 mm to about 10 mm, or in the range of about 0.5 mm to about 6 mm, or in the range of about 0.75 mm to about 4 mm, or in the range of about 1 mm to about 2 mm.

In some embodiments, the distance Dᵢ from the band 220 to the substrate 160 can be any suitable distance. In some embodiments, the distance Dᵢᵢ is measured from the inner edge 225i of the band 220 to the outer peripheral edge 161 of the substrate 160. The distance Dᵢᵢ can be any suitable distance. In some embodiments, the distance Dᵢᵢ is in the range of about 0.1 mm to about 5 mm, or in the range of about 0.2 mm to about 3 mm. In some embodiments, when a substrate 160 is present in the support region 210, the outer band 220 is spaced from the outer peripheral edge 161 of the substrate 160 by an average distance Dᵢᵢ in the range of about 0.1 mm to about 5 mm, or in the range of about 0.2 mm to about 3 mm, or in the range of about 0.5 mm to about 5 mm.

The shape of the posts 225 can be any suitable shape. In the illustrated embodiments, the posts 225 are cylindrical shaped components that extend a height H_{S} from the top surface 204 of the body 202. In some embodiments, the height H_{S} is in the range of about 0.2 mm to about 5 mm. In some embodiments, the sidewall of the post 225 closest to the substrate 160 extends substantially perpendicular to the top surface 204 of the support body 202. As used in this manner, the term “substantially perpendicular” means at an angle to the top surface 204 in the range of about 80° to about 110°.

The width W_{b} of the band 220 is defined as the distance between the inner face 225i and the outer face 225o. In some embodiments, the width W_{b} of the band 220 is in the range of about 0.5 mm to about 25 mm, or in the range of about 1 mm to about 20 mm, or in the range of about 2 mm to about 15 mm, or in the range of about 3 mm to about 10 mm.

The height H_{S} of the band 220, as shown in FIG. 5, is defined as the distance from the top surface 204 of the body 202 to the top surface 226 of the post 225. In some embodiments, the height H_{S} of the band 220 is in the range of about 0.2 mm to about 20 mm, or in the range of about 0.5 mm to about 15 mm, or in the range of about 0.75 mm to about 10 mm, or in the range of about 1 mm to about 5 mm. In some embodiments, the band 220 has a height H_{S} sufficient so that the top surface 226 of the post 225 is substantially coplanar with the top surface 161 of the substrate 160. As used in this manner, the term “substantially coplanar” means that the major plane formed by the substrate 160 is within ±0.5 mm of the major plane of the top surface 226 of the post 225.

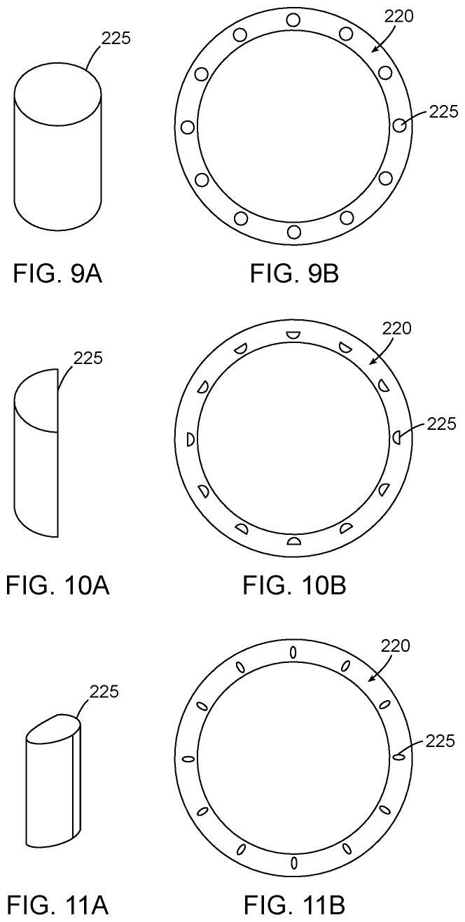

The shape of the posts 225 can vary to change the flow of gases passing the posts 225. FIGS. 9A through 11B illustrate three possible, non-limiting, examples of post 225 shapes. In FIG. 9A, the post 225 is cylindrical. FIG. 9B illustrates an arrangement of the posts 225 of FIG. 9A to form band 220 according to one or more embodiment. In FIG. 10A, the post 225 is a half-cylinder. FIG. 10B illustrates an arrangement of posts 225 of FIG. 10A to form band 220 according to one or more embodiment. In FIG. 11A, the post is tear-drop shaped. FIG. 11B illustrates an arrangement of posts 225 of FIG. 11A to form band 220.

Referring back to FIG. 1, the substrate support pedestal 200 of some embodiments includes a pedestal shaft 250. The pedestal shaft 250 extends from the bottom surface 206 of the body 202. In some embodiments, the pedestal shaft 250 is integrally formed with the support body 202. In some embodiments, the pedestal shaft 250 is a separate component from the support body 202.

The pedestal shaft 250 of some embodiments comprises a gas line 255 that extends through the pedestal shaft 250 to an opening 213 in the support region 210. In some embodiments, there is a pedestal shaft 250 with a gas line 255 extending through the pedestal shaft to openings 213 support region 210 through openings 212.

In some embodiments, the support body 202 is an electrostatic chuck. As will be understood by the skilled artisan, an electrostatic chuck includes one or more electrode 260 which can be polarized to chuck a substrate to the support body 202. In some embodiments, the support body 202 includes one or more thermal element 265 within the thickness of the support body 202. The thermal elements 265 are connected to a power source (not shown) which can cause a change in the temperature of the support body 202. In some embodiments, the thermal elements 265 are heating coils. In some embodiments, the thermal elements 265 are cooling elements. In some embodiments, the thermal elements 265 comprise heating coils and cooling elements to control the temperature of the substrate.

Referring back to FIG. 1, some embodiments include one or more of a flow controller 170, pressure gauge 172, pump 174 or feedback circuit 176 connected to the gas line 255. The skilled artisan will be familiar with flow controllers, pressure gauges, pumps and feedback circuits for use with processing chambers. In some embodiments, the flow controller 170, pressure gauge 172, pump 174 and feedback circuit 176 are used to control a flow of backside gas through the gas line 255 into the support region 210.

In the embodiment illustrated in FIG. 1, the flow controller 170 is upstream of and in fluid communication with the gas line 255. The pressure gauge 172 is downstream of and in fluid communication with the gas line 255 and the pump 174 is downstream of the pressure gauge 172 and in fluid communication with the gas line 255. The combination of the flow controller 170, pressure gauge 172 and pump 174 can be used to control the backside gas pressure provided to the support region 210. In some embodiments, the feedback circuit 176 is configured to measure pressure in the gas line 255 and adjusts the flow controller 172 to maintain a uniform pressure within the gas line 255.

In some embodiments, the substrate support pedestal 200 or processing chamber 100, or both, is connected to a controller 190. The controller 190 can be configured to control and/or receive information from one or more of the flow controller 170, pressure gauge 172, pump 174 or feedback circuit 176. In some embodiments, the feedback circuit 176 is a part of the controller 190.

In the processing chamber 100 of FIG. 1, the substrate support pedestal 200 within the interior volume 105 of the processing chamber 100 defines a reaction space 106 adjacent the top surface 204 of the support body 202. The gas distribution assembly 110 directs a flow 105 of gas toward the top surface 204 of the support body 202 and substrate 160. A reaction space pressure gauge 109 is configured to measure the pressure within the reaction space 106.

Some embodiments of the processing chamber 100 include at least one controller 190 coupled to one or more of the processing chamber 100, pedestal 200, flow controller 170, pressure gauge 172, pump 174, feedback circuit 176, reaction space pressure gauge 108 or gas distribution assembly 110. In some embodiments, there are more than one controller 190 connected to the individual components and a primary control processor is coupled to each of the separate controller or processors to control the system. The controller 190 may be one of any form of general-purpose computer processor, microcontroller, microprocessor, etc., that can be used in an industrial setting for controlling various chambers and sub-processors.

The at least one controller 190 can have a processor 192, a memory 194 coupled to the processor 192, input/output devices 196 coupled to the processor 192, and support circuits 198 to communication between the different electronic components. The memory 194 can include one or more of transitory memory (e.g., random access memory) and non-transitory memory (e.g., storage).

The memory 194, or a computer-readable medium, of the processor may be one or more of readily available memory such as random access memory (RAM), read-only memory (ROM), floppy disk, hard disk, or any other form of digital storage, local or remote. The memory 194 can retain an instruction set that is operable by the processor 192 to control parameters and components of the system. The support circuits 198 are coupled to the processor 192 for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 190 has one or more configurations to execute individual processes or sub-processes to perform embodiments of the method. The controller 190 can be connected to and configured to operate intermediate components to perform the functions of the methods. For example, the controller 190 can be connected to and configured to control one or more of gas valves, actuators, motors, slit valves, vacuum control, etc.

The controller 190 or non-transitory computer readable medium of some embodiments has one or more configurations or instructions selected from: a configuration to move a substrate on a robot to the lift pins; a configuration to load and/or unload substrates from the system; a configuration to provide a flow of gas through the gas distribution assembly, a configuration to measure the reaction space pressure; a configuration to measure the pressure in the gas line; a configuration to control a flow controller to control a flow of backside gas to the gas line; a configuration to control the flow of gas to the pump from the gas line and flow controller to regulate the pressure in the gas line; a configuration to adjust the flow controller to maintain a uniform pressure within the gas line based on readings from the reaction space pressure gauge; a configuration to maintain a positive pressure in the inner pocket region relative to the reaction space; a configuration to control the electrostatic chuck and/or electrode within the support body; a configuration to control the thermal element to control the temperature of the support body.

In some embodiments, the non-transitory computer readable medium or controller includes instructions to flow a backside gas to a support region of the substrate support pedestal; a configuration to flow a process gas to the reaction space in the processing chamber; a configuration to determine a pressure differential between the support region and an outer region at an outside of the band or the pressure of the reaction space; and/or controlling the flow of backside gas to the support region to maintain a uniform flow of gas from the support region through the band.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A substrate support pedestal comprising a support body having a top surface and a bottom surface defining a thickness, the top surface having a support region bounded by an outer band and comprising one or more openings in the top surface, the outer band comprising a plurality of spaced apart posts.

2. The substrate support pedestal of claim 1, wherein each of the spaced apart posts have a cross-sectional width and the combined widths of the spaced apart posts is less than or equal to 50% of a circumference of the support region.

3. The substrate support pedestal of claim 2, wherein the combined widths of the spaced apart posts is less than or equal to 25% of the circumference of the support region.

4. The substrate support pedestal of claim 2, wherein the combined widths of the spaced apart posts is less than or equal to 10% of the circumference of the support region.

5. The substrate support pedestal of claim 1, wherein when a substrate is present in the support region, the outer band provides a physical boundary to keep the substrate centered within the band.

6. The substrate support pedestal of claim 5, wherein there is substantially no dead volume around the substrate.

7. The substrate support pedestal of claim 1, wherein when a substrate is present in the support region, the outer band is spaced from an outer peripheral edge of the substrate by an average distance in the range of about 0.5 mm to about 5 mm.

8. The substrate support pedestal of claim 1, wherein the each of the spaced apart posts has a height in the range of about 0.2 mm to about 5 mm.

9. The substrate support pedestal of claim 1, wherein spacing between the posts are substantially the same.

10. The substrate support pedestal of claim 1, wherein the posts have a sidewall extending substantially perpendicular to the top surface of the support body.

11. The substrate support pedestal of claim 1, wherein the support body is an electrostatic chuck comprising electrodes.

12. The substrate support pedestal of claim 1, wherein the support body comprises heater coils within the thickness of the support body.

13. The substrate support pedestal of claim 1, further comprising a pedestal shaft extending from the bottom surface of the support body.

14. The substrate support pedestal of claim 13, wherein the pedestal shaft comprises a gas line extending through the pedestal shaft to the one or more opening in the support region.

15. The substrate support pedestal of claim 14, wherein the one or more openings in the support region are in fluid communication with one or more of a vacuum source, a reactive gas source or a purge gas source.

16. The substrate support pedestal of claim 14, further comprising a flow controller, pressure gauge, pump and feedback circuit connected to the gas line to control a flow of gas through the gas line into the support region.

17. The substrate support pedestals of claim 16, further comprising a controller configured to control and/or receive information from one or more of the flow controller, pressure gauge, pump or feedback circuit.

18. The substrate support of claim 17, wherein the flow controller is upstream of and in fluid communication with the gas line, the pressure gauge is downstream of and in fluid communication with the gas line and the pump is downstream of the pressure gauge and in fluid communication with the gas line, and the feedback circuit is configured to measure pressure in the gas line and adjust the flow controller to maintain a uniform pressure within the gas line.

19. A processing chamber comprising:
a substrate support assembly comprising a plurality of substrate support pedestals, each of the substrate support pedestals comprising a support body having a top surface and a bottom surface defining a thickness, the top surface having a support region bounded by an outer band and comprising one or more openings in the top surface, the outer band comprising a plurality of spaced apart posts, the substrate support assembly rotatable around a central axis; and
a plurality of gas distribution assemblies spaced around in inside of the processing chamber, each of the gas distribution assemblies configured to direct a flow of gas toward the top surface of the support body.

20. A processing method comprising:
providing a flow of gas to a support region of a substrate support pedestal, the substrate support pedestal comprising, a support body having a top surface and a bottom surface defining a thickness, the top surface having a support region bounded by an outer band and comprising one or more openings in the top surface, the outer band comprising a plurality of spaced apart posts; and
evacuating the support region to provide a purge flow from the support region pas the spaced apart posts bounding the support region.
